(19) United States
(12) Patent Application Publication
(10) Pub. No.: US 2007/0088913 A1
(43) Pub. Date: Apr. 19, 2007

(54) Portable data transfer device

(75) Inventor: Jack Hu, Jhonghe City (TW)

Correspondence Address: HDSL, 4331 STEVENS BATTLE LANE, FAIRFAX, VA, 22033, US

(73) Assignee: EZPnP Technologies Corp.

(21) Appl. No.: 11/249,419

(22) Filed: Oct. 14, 2005

(51) Int. Cl. G06F 12/00; H05K 7/16

(52) U.S. Cl. 711/115; 361/725

(57) ABSTRACT

A portable data transfer device includes a host equipped with a plurality of slots for installing various types of memory cards. A receiving slot is formed in the host to provide a replaceable hard disk drive or compact disk drive. To data transfer data from the memory cards to the hard disk or a blank compact disk, the memory card is inserted into the corresponding slot, and the hard disk drive or the compact disk drive is installed in the receiving slot. Thereby, the data transfer or reproduction can be performed more conveniently.

### BACKGROUND OF THE INVENTION

1. Field of Invention

The present invention relates in general to a data transfer device, and more particular, to a portable data transfer device to transfer data from a memory card to a hard disk or a blank compact disk.

2. Related Art

In recent years, digital products such as laptop computers, cell phones, personal digital assistant and digital cameras have become more and more popular to provide various applications such as image/sound multimedia and data network transmission in our daily lives. The data of these digital products are normally saved in the light, thin, short and small memory cards such as secured digital (SD) card, compact flash (CF) card, smart media (SM) card, memory stick (MS) and multimedia card (MMC).

When the user needs to access the data saved in the memory card or when the capacity of the memory card is full, the data stored therein are transferred to a hard disk of a computer via a card reader installed at the computer. When the connection between the memory card and the computer is established, the card reader is then operative to save the data saved in the memory card into the hard disk. Or alternatively, a connection line (having USB connection port) can be used to connect the digital product and the computer to save the data stored of the memory card into the hard disk.

Currently, most of the digital products are portable and used outdoors. When the memory card is full, the data saved therein cannot be transferred into the computer immediately. Therefore, one or more than one backup memory card is always required. However, as the price of the memory cards are relatively high, the backup memory card is thus a burden to the user.

Therefore, a hard-disk type or a compact-disk type data transfer device is developed to provide direct storage of the data into the hard disk. Alternatively, the data can be burned on a blank compact disk by a compact disk drive for backup of the data. However, the user has to choose between the hard disk or the compact disk for transferring and saving the data. Therefore, when the user has only the compact-disk type data transfer device, the data has to be saved in a blank compact disk first before being saved into the hard disk. This causes great inconvenience for the user. In addition, the hard disk of the hard-disk type data transfer device is fitted in the data transfer device. During transportation, the data saved in the hard disk is easily damaged due to vibration or impact. Therefore, this type of data transfer device is not a safe data storage device.

### SUMMARY OF THE INVENTION

A portable data transfer device includes a replaced magnetic storage device or a replace optical storage device is provided for transfer data saved in a memory card.

Accordingly, a portable data transfer device of the present invention includes a host equipped with a plurality of slots for installing various types of memory cards. A receiving slot is formed in the host to provide a replaceable hard disk drive or compact disk drive. To data transfer data from the memory cards to the hard disk or a blank compact disk, the memory card is inserted into the corresponding slot, and the hard disk drive or the compact disk drive is installed in the receiving slot. Thereby, the data transfer or reproduction can be performed more conveniently.

To install the magnetic storage device such as a hard disk, a fitting box having a size substantially the same as a receiving slot formed in a host is provided. The hard disk is installed in the fitting box, and the fitting box is then inserted into the receiving slot The hard disk includes a connector connected to a corresponding connector of a control circuit board of the host. Thereby, the hard disk is in electrical communication with the host, and the data saved in the memory card can be transferred into the hard disk.

### BRIEF DESCRIPTION OF THE DRAWINGS

The present invention will become more fully understood from the detailed description given hereinbelow illustration only, and thus are not limitative of the present invention, and wherein:

FIG. 1 shows the perspective view of a data transfer device as provided;

FIG. 2 shows an exploded view of a host including a hard disk carried by a fitting box to be inserted into a receiving slot of the host;

FIG. 3 shows the assembly of the host and the hard disk;

FIG. 4 shows the assembly as shown in FIG. 3 from another view point;

FIG. 5 shows the connection status between the host and a memory card;

FIG. 6 shows an exploded view of a host and a compact disk drive to be installed in the host; and

FIG. 7 shows the operation of the host including the compact disk drive.

### DETAILED DESCRIPTION OF THE INVENTION

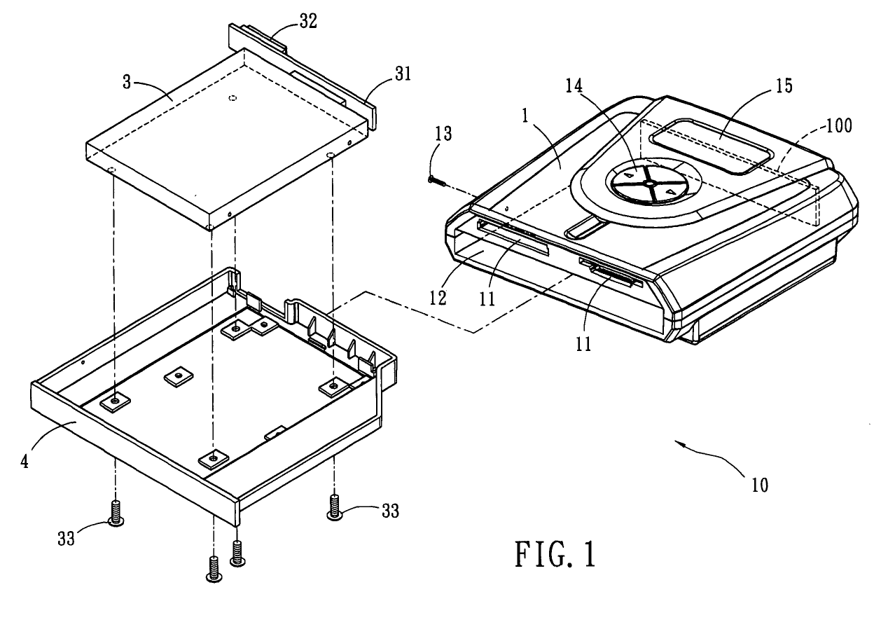

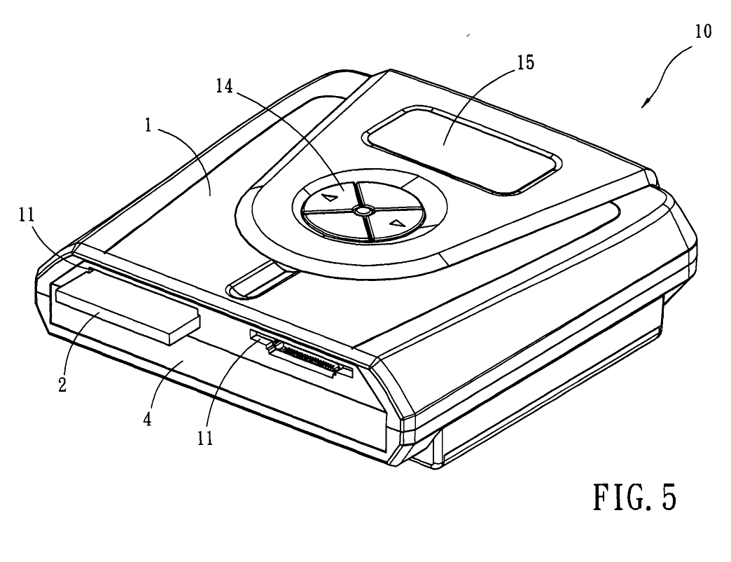

Referring to FIG. 1, the portable data transfer device 10 includes a host 1, in which a control circuit board 100, a plurality of slots suitable for installing memory cards 2 (as shown in FIG. 5) of various specifications are installed. In this embodiment, the host 1 includes two slots 11 each being operative to receive different types of memory cards 2 such as SD, CF, MD and SIM cards.

A receiving slot 12 is formed in the host 1 allowing a replaceable magnetic storage device or a replaceable optical storage device installed therein. In this embodiment, the magnetic storage device includes a hard disk drive 3, for example. The hard disk drive 3 has one end connected to a circuit board 31 on which a connector 32 is formed to connect the corresponding connector of the control circuit board 100 of the host 1. The hard disk drive 3 is inserted and carried by a fitting box 4, which is then inserted into the receiving slot 12 of the host 1. Therefore, the size of the fitting box 4 is substantially the same as that of the receiving slot 12 of the host 1.

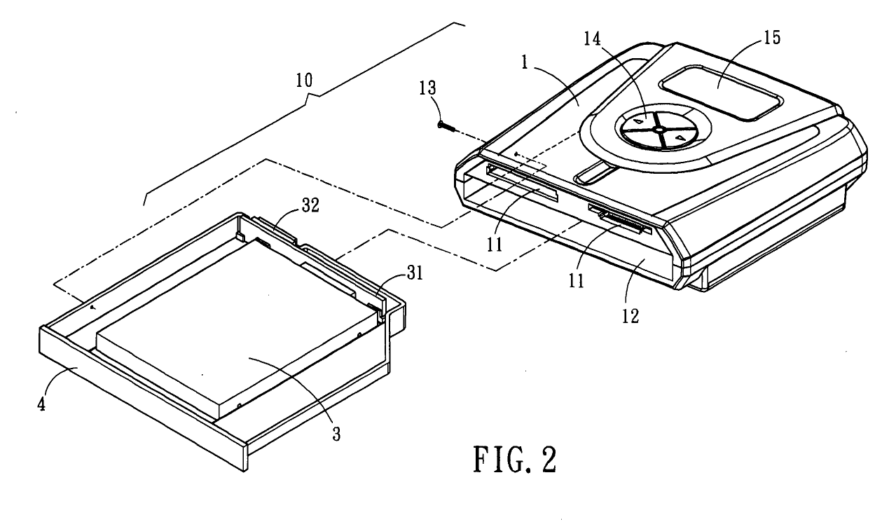

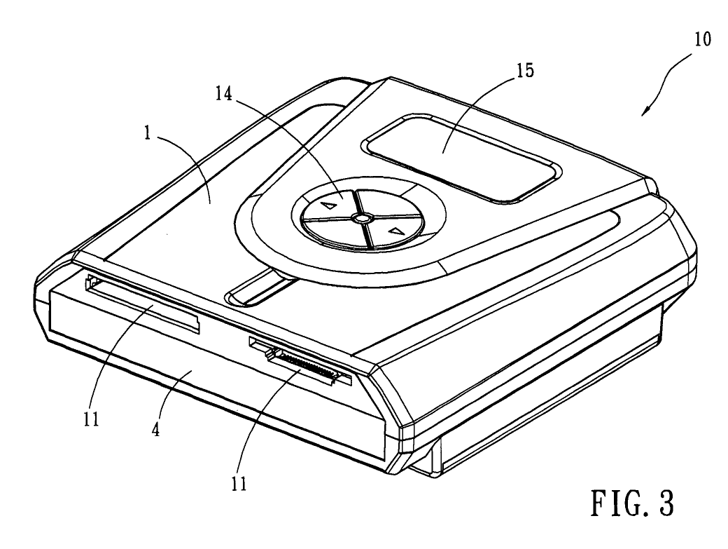

Referring to FIGS. 2 and 3, to install the hard disk drive 3 into a portable data transfer device 10, the hard disk 3 is fitted into the fitting box 4 via fitting elements 33. The connector 32 of the hard disk 3 preferably extends out of the fitting box 32. The fitting box 4 is then inserted into the receiving slot 12 of the host 1. The connector 32 of the hard disk 3 is then connected to the connector of the host 1. Fitting elements 13 such as screws, bolts, latching pins or other latching elements can be used to fit the hard disk 3 with the host 1. In this embodiment, screws are used to extend through a side board of the host 1 and to hock the side panel of the hard 3. Other fitting methods can also be used for fitting the hard disk 3 with the host 1.

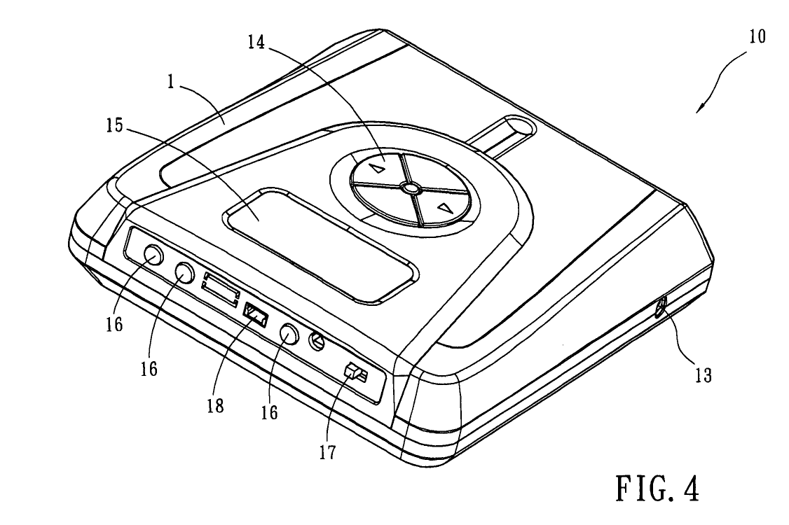

Referring FIG. 4, a selection key or button 14 and a liquid crystal display (LCD) 15 are formed on the host 1. A plurality of function keys or buttons 16, a power switch 17 and a mini USB slot 18 are also installed on the other side of the memory card slots 11.

As shown in FIG. 5, to transfer data from the memory card 2 to the hard disk 3, the memory card 2 is inserted into the corresponding slot 11. By operating the keys 14 on the host 1, the data are easily transferred from the memory card 2 to the hard disk 3. Backup operation can then be easily performed, and the data can be erased from the memory card 2 to release the storage space thereof. Therefore, the digital product can be used outdoors without worrying about insufficient storage capacity.

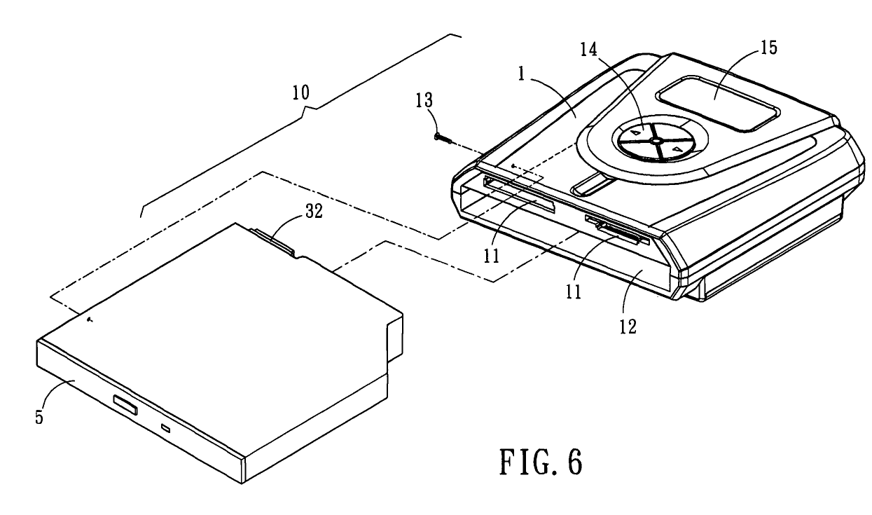

Referring to FIG. 6, the receiving slot 12 of the portable data transfer data 10 can also allow installation of an optical storage device. In this embodiment, a compact disk drive 5 is used and configured with a dimension substantially the same as that of the receiving slot 12. Therefore, by installing the compact disk drive 5 into the receiving slot 12, fitting elements 13 can be used to interlock or block side panels of the compact disk drive 5. Thereby, the compact disk 5 is prevented from sliding out of the host 1.

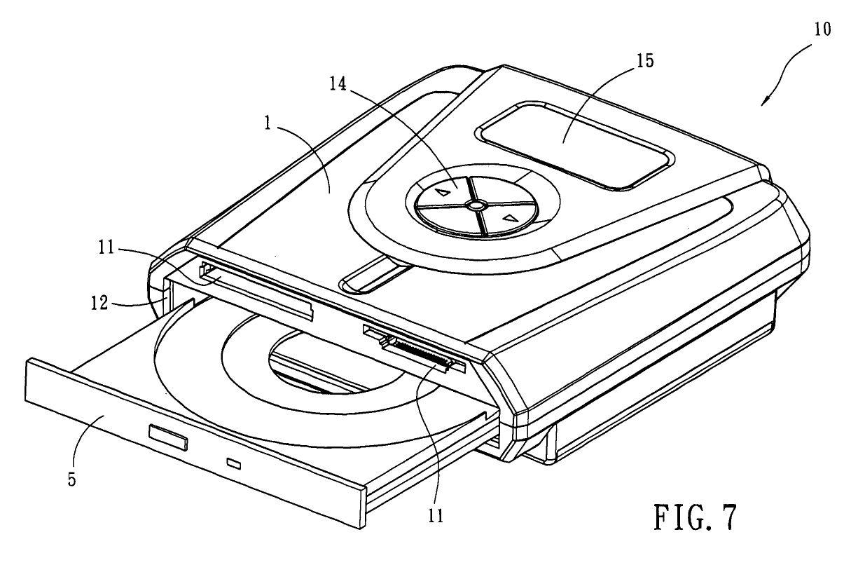

Referring to FIG. 7, to transfer the data from the memory card 2 to a blank compact disk, the blank compact disk is inserted into the compact disk drive 5. By operating the keys 14 on the host, the data can be easily transferred from the memory card 2 to the blank compact disk, and a backup thereof can be easily obtained. The data can the be erased from the memory card 2 to release storage space thereof.

According to the above, the portable data transfer device 10 as provided allows the installation of a replaceable hard disk drive 3 and a replaceable compact disk 5. Therefore, data saved in memory cards 2 of various specifications can be transferred to either the hard disk 3 or a blank compact disk as desired. By the replaceable structure of the hard disk drive 3 and the compact disk drive 5, the user can selectively make backup data in either drive.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A portable data transfer device, having a host which comprises:
a control circuit board installed therein;
at least one memory card slot for receiving at a memory card of at least one specification; and
a receiving slot allowing a replaceable magnetic storage device or a replaceable optical storage device to installed therein.

2. The device of claim 1, wherein the magnetic storage device includes a hard disk drive having a circuit board at one side thereof and a connector mounted on the circuit board to connect a corresponding connector of the controller circuit board.

3. The device of claim 2, further comprising a fitting box having a dimension substantially the same as that of the receiving slot for carrying the hard disk therein and to be inserted into the receiving slot.

4. The device of claim 1, wherein the optical storage device includes a writable and readable compact disk drive.

5. The device of claim 1, further comprising at least one fitting element for fitting the magnetic or optical storage device within the receiving slot of the host.

6. The device of claim 5, wherein the fitting element includes a screw, a bolt or a position pin extending through a side board of the host towards a side panel of the magnetic or optical storage device for holding the magnetic or optical storage device in the host.
